(19) United States
(12) Patent Application Publication
(10) Pub. No.: US 2024/0107147 A1
(43) Pub. Date: Mar. 28, 2024

(54) CAMERA MODULE COMPENSATING FOR LOSS OF FOCUS BY HEAT-DEFORMATION AND ELECTRONIC DEVICE USING THE SAME

(71) Applicant: TRIPLE WIN TECHNOLOGY(SHENZHEN) CO.LTD., Shenzhen (CN)

(72) Inventors: HAI-XIN JIN, Jincheng (CN); ZHI-WEI LI, Jincheng (CN)

(21) Appl. No.: 18/071,421

(22) Filed: Nov. 29, 2022

(30) Foreign Application Priority Data
Sep. 22, 2022 (CN) 202211160713.5

(51) Int. Cl. H04N 23/57; G02B 7/02; H04N 23/54; H04N 23/55; H05K 1/02

(52) U.S. Cl. CPC H04N 23/57; G02B 7/028; H04N 23/54; H04N 23/55; H05K 1/0274

(57) ABSTRACT

A camera module compensating for loss of focus caused by heat-deformation of a lens assembly above a photosensitive element includes the lens assembly, the photosensitive element, a circuit board, and a focusing assembly. The photosensitive element receives light through the lens assembly. The focusing assembly is arranged to apply deformation when temperature changes by moving the photosensitive element away from or toward the lens assembly, so correcting a focal length of the lens assembly on the photosensitive element. An electronic device is also disclosed.

### TECHNICAL FIELD

The present disclosure relates to the field of optical imaging technology, in particular to a camera module and an electronic device.

### BACKGROUND

Material of a lens is mostly plastic and when a camera device operates for a long time, the temperature rises. As the camera device is heated, the volume of the material made of the camera device changes, resulting in changes in a focal length of the lens which blurs the image, and reduced the image quality. The existing automatic focusing process adopts voice coil motor (VCM) technology, the physical focusing mode with clear imaging surface is realized by moving the entire lens group. The existing voice coil motor technology requires complex calibration process, and the automatic focusing response time is long.

Therefore, improvement is desired.

### SUMMARY OF THE DISCLOSURE

The embodiment of the present disclosure aims to provide a camera module and an electronic device. The present disclosure allows focusing according to temperature change.

The present disclosure provides a camera module. The camera module includes a lens assembly, a photosensitive element, a circuit board, and a focusing assembly. The photosensitive element receives light entering the lens assembly. The circuit board is electrically connected to the photosensitive element. The photosensitive element is connected to the focusing assembly. The focusing assembly is arranged to produce deformation when temperature changes, to move the photosensitive element away from or toward the lens assembly, thereby regulating a focal length between the photosensitive element and the lens assembly.

The embodiments of the present disclosure include the following technical effects: when heating of the photosensitive element causes the focal length between the camera lens and the photosensitive element to become longer, the present disclosure generates deformation through the focusing assembly to make the photosensitive element move away from the camera lens, so as to adjust the focal length between the photosensitive element and the camera lens, so that the focus of the camera lens remains located on the photosensitive element, to achieve automatic focusing and ensure imaging quality.

In some embodiments, the focusing assembly includes a first metal plate, a second metal plate, and a plurality of connecting members, one end of each connecting member is connected to the first metal plate, and other end of each connecting member is connected to the second metal plate, the first metal plate and the second metal plate are arranged at intervals, the photosensitive element is arranged on a surface of the second metal plate opposite to the first metal plate. When temperature of the connecting member changes, the connecting member is deformed to move the second metal plate relative to the first metal plate.

In some embodiments, the first metal plate defines a first concavity, and the second metal plate is arranged in the first concavity, the connecting member is connected to an edge of the first concavity and an edge of the second metal plate, and the second metal plate is spaced from the edge and bottom of the first concavity.

In some embodiments, the connecting member includes a first connecting plate and a second connecting plate arranged in a stack, the second connecting plate faces the first metal plate, the first connecting plate is away from the first metal plate, and the first connecting plate and the second connecting plate have different thermal expansion ratios.

In some embodiments, the thermal expansion ratio of the first connecting plate is greater than the thermal expansion ratio of the second connecting plate, and a deformation degree of the first connecting plate is greater than a deformation degree of the second connecting plate at same temperature.

In some embodiments, the circuit board includes a first circuit board and a second circuit board, the first circuit board is connected to the first metal plate, the second circuit board is connected to the second metal plate, the first circuit board surrounds a periphery of the second circuit board, and the first circuit board is flexibly connected to the second circuit board. The second circuit board surrounds a periphery of the photosensitive element, and the second circuit board is electrically connected to the photosensitive element.

In some embodiments, the camera module further includes a supporting plate, wherein the supporting plate is connected to the first circuit board and is spaced from the second circuit board.

In some embodiments, the supporting plate defines an installation portion, and an optical filter is arranged in the installation portion, the filter is located between the lens assembly and the photosensitive element.

In some embodiments, the lens assembly comprises a bracket and a camera lens, the camera lens is mounted on the bracket, and the bracket is connected to a side of the supporting plate away from the first circuit board.

In some embodiments, the camera module further includes an electrical connector, wherein the electrical connector is flexibly connected to the first circuit board, and the electrical connector connects to an external device.

The embodiment of the present disclosure further provides an electronic device, the electronic device includes a camera module of any of the above embodiments.

### BRIEF DESCRIPTION OF THE DRAWINGS

FIG. 1 is a schematic diagram of a camera module according to an embodiment of the present disclosure.

FIG. 2 is a diagram of the camera module disassembled according to an embodiment of the present disclosure.

FIG. 3 is a schematic diagram of a photosensitive element, a circuit board, and a focusing assembly according to an embodiment of the present disclosure.

FIG. 4 is a sectional diagram of the camera module according to an embodiment of the present disclosure.

FIG. 5 is a schematic diagram of the focusing assembly at room temperature according to an embodiment of the present disclosure.

FIG. 6 is a schematic diagram of the focusing assembly at a high temperature according to an embodiment of the present disclosure.

FIG. 7 is a schematic diagram of an electronic device according to other embodiment of the present disclosure.

### DETAILED DESCRIPTION

The following will describe the technical solutions in the embodiments of the present disclosure in combination with the drawings in the embodiments of the present disclosure. Obviously, the described embodiments are only part of the embodiments of the present disclosure, not all of them.

It should be noted that when a component is stated as “installed in” another component, it can be directly on the other component or there can be a component therebetween. When a component is considered to be “set on” another component, it can be directly set on the other component or there may be other connected components at the same time.

Unless otherwise defined, all technical and scientific terms used herein have the same meanings as those commonly understood by those skilled in the technical field of the present disclosure. The terms used in the specification of the present disclosure herein are only for the purpose of describing specific embodiments and are not intended to limit the present disclosure. The term “and/or” as used herein includes any and all combinations of one or more related listed items.

The present disclosure provides a camera module. The camera module includes a lens assembly, a photosensitive element, a circuit board, and a focusing assembly. The photosensitive element is configured for receiving light entering the lens assembly. The circuit board is electrically connected to the photosensitive element. The photosensitive element is connected to the focusing assembly. The focusing assembly is arranged to produce deformation when temperature changes, to move the photosensitive element away from or toward the lens assembly, thereby regulating a focal length between the photosensitive element and the lens assembly. When heating of the photosensitive element causes the focal length between the camera lens and the photosensitive element to become longer, the present disclosure generates deformation through the focusing assembly to move the photosensitive element away from the camera lens, so as to adjust the focal length between the photosensitive element and the camera lens, so that the focus of the camera lens remains located on the photosensitive element, to achieve automatic focusing and ensure the imaging quality.

Some embodiments of the present disclosure will be described in detail below in combination with the accompanying drawings.

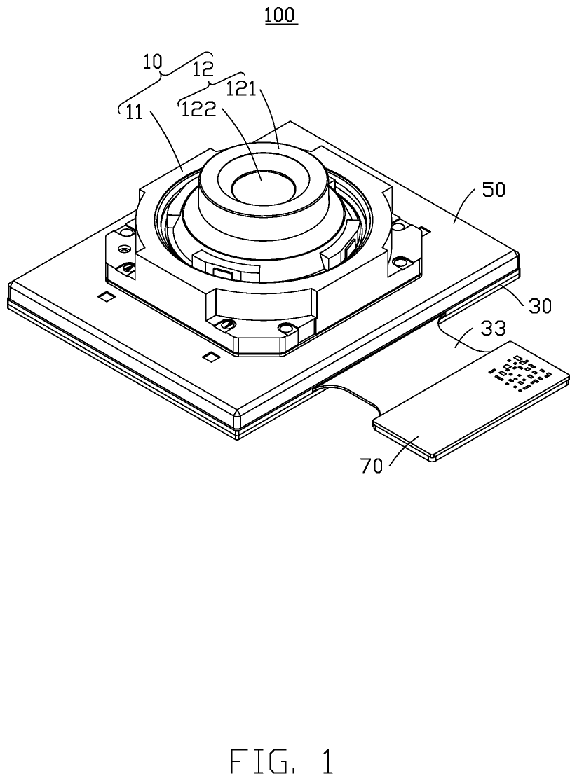

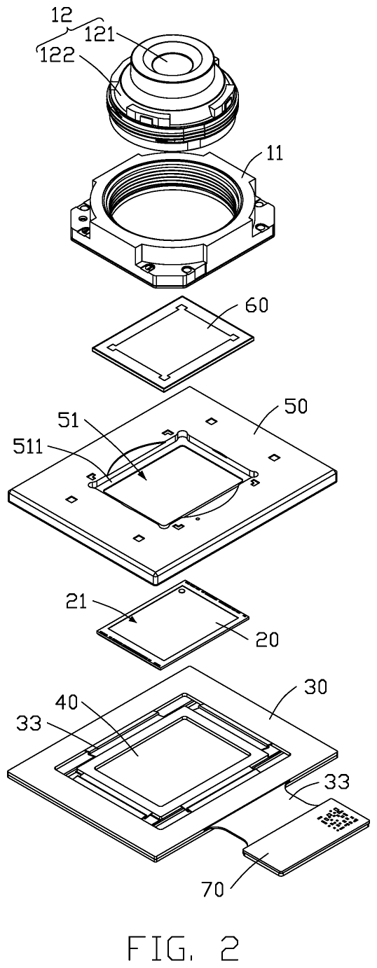

FIGS. 1-2 illustrate a camera module 100 in accordance with an embodiment of the present disclosure.

The camera module 100 includes a lens assembly 10, a photosensitive element 20, a circuit board 30, and a focusing assembly 40. The photosensitive element 20 is disposed between the lens assembly 10 and the focusing assembly 40. The light from the object side is incident to the lens assembly 10 and falls onto the photosensitive element 20 at the image side of the lens assembly 10, the photosensitive element 20 converts the received light into a corresponding electrical signal and converts it into an image through an external image processing device. The circuit board 30 is electrically connected to the photosensitive element 20, and the circuit board 30 connects to an external image processing device and/or an external power supply. The photosensitive element 20 is thermally connected with the focusing assembly 40. When the photosensitive element 20 becomes hot, part of the heat of the photosensitive element 20 is transmitted to the focusing assembly 40, causing the temperature of the focusing assembly 40 to change, the focusing assembly 40 deforms to move the photosensitive element 20 away from or nearer the lens assembly 10, thereby adjusting the focal length between the photosensitive element 20 and the lens assembly 10.

When the photosensitive element 20 becomes hot, part of the heat of the photosensitive element 20 is transmitted to the lens assembly 10, causing the lens assembly 10 to be thermally deformed, making the focal length between the lens assembly 10 and the photosensitive element 20 longer, changing the focal point of the lens assembly 10 from the photosensitive element 20, and blurring the image. Part of the heat of the photosensitive element 20 is transmitted to the focusing assembly 40. When the temperature of the focusing assembly 40 rises, the focusing assembly 40 will deform, moving the photosensitive element 20 away from the lens assembly 10, increasing the focal length between the photosensitive element 20 and the lens assembly 10, so that the focal point of the lens assembly 10 is still located on the photosensitive element 20, and ensuring the imaging quality. When the photosensitive element 20 cools, the lens assembly 10 recovers its original shape, the focal length between the lens assembly 10 and the photosensitive element 20 correspondingly shortens, the temperature of the focusing assembly 40 correspondingly decreases, and the focusing assembly 40 resets, the photosensitive element 20 can be moved in the direction closer to the lens assembly 10, so that the focus of the lens assembly 10 remains on the photosensitive element 20.

Referring to FIG. 2, in one embodiment, the lens assembly 10 includes a bracket 11 and a camera lens 12, and the camera lens 12 is installed in the bracket 11.

The camera lens 12 includes a housing 121 and a lens 122. The lens 122 is installed in the housing 121, and the housing 121 is installed in the bracket 11. The housing 121 is threaded to match the bracket 11. Optionally, multiple lenses 122 can be set and used in combination. Optionally, the lens 122 is made of plastic. The lenses 122 can be made of plastic to reduce the weight of the lens assembly 10, speeding up production and lowering cost.

In one embodiment, the camera module 100 further includes a supporting plate 50. The supporting plate 50 is disposed between the 30 and the bracket 11. One side of the supporting plate 50 is connected to the circuit board 30, and other side of the supporting plate 50 is connected to the bracket 11. Optionally, the bracket 11 is bonded to the side of the supporting plate 50 away from the circuit board 30, and the supporting plate 50 is bonded to the side of the circuit board 30 away from the focusing assembly 40.

In one embodiment, the camera module 100 further includes an optical filter 60. The optical filter 60 is connected to the supporting plate 50. The optical filter 60 is located between the camera lens 12 and the photosensitive element 20 and is spaced from the camera lens 12 and the photosensitive element 20. Optionally, the supporting plate 50 is provided with an installation portion 51, and the installation portion 51 penetrates the supporting plate 50. The inner wall of the peripheral side of the installation portion 51 is provided with a convex portion 511, and the optical filter 60 is bonded to the convex portion 511. Optionally, the optical filter 60 includes an infrared filter. The infrared filter filters the imaging light, specifically to isolate and block infrared light and prevent the infrared light from being received by the photosensitive element 20, so as to prevent the infrared light from affecting the color and definition of the normal image, thus improving the imaging quality of the camera module 100.

In one embodiment, the photosensitive element 20 includes a photosensitive surface 21, the photosensitive surface 21 faces the camera lens 12, and the photosensitive element 20 receives light from the camera lens 12.

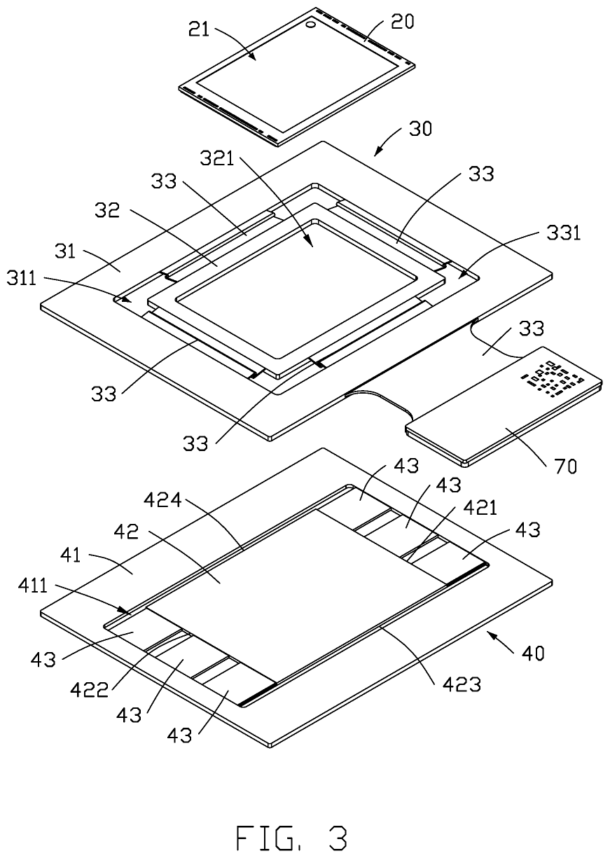

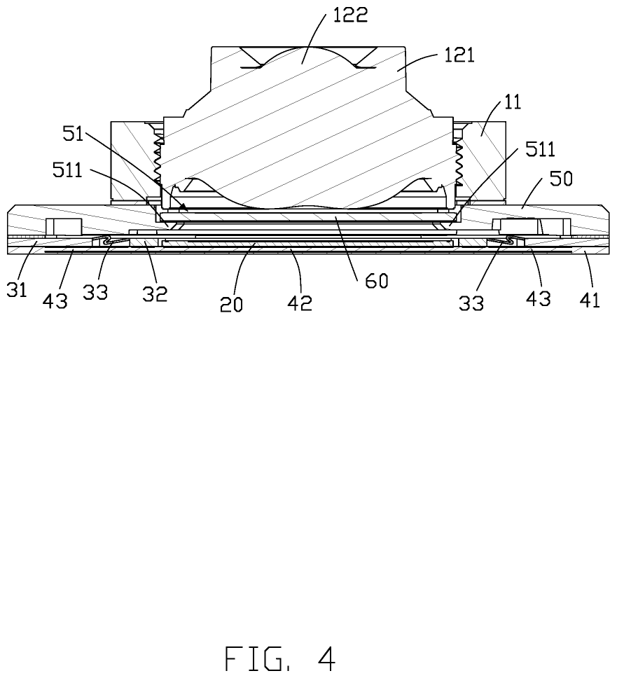

Referring to FIG. 2, FIG. 3 and FIG. 4, in one embodiment, the circuit board 30 includes the first circuit board 31 and the second circuit board 32. The first circuit board 31 and the second circuit board 32 are connected to one side surface of the focusing assembly 40 facing the camera lens 12. The first circuit board 31 surrounds the periphery of the second circuit board 32, and the first circuit board 31 is flexibly connected to the second circuit board 32. The second circuit board 32 surrounds the periphery of the photosensitive element 20, and the second circuit board 32 is electrically connected to the photosensitive element 20.

In one embodiment, the first circuit board 31 defines a first opening 311, the second circuit board 32 is arranged in the first opening 311, and the edge of the second circuit board 32 is spaced from the edge of the first opening 311. The inner edge of the first circuit board 31 and the outer edge of the second circuit board 32 are connected by the flexible circuit board 33. Optionally, each inner edge of the first circuit board 31 and each outer edge corresponding to the second circuit board 32 are connected through the flexible circuit board 33.

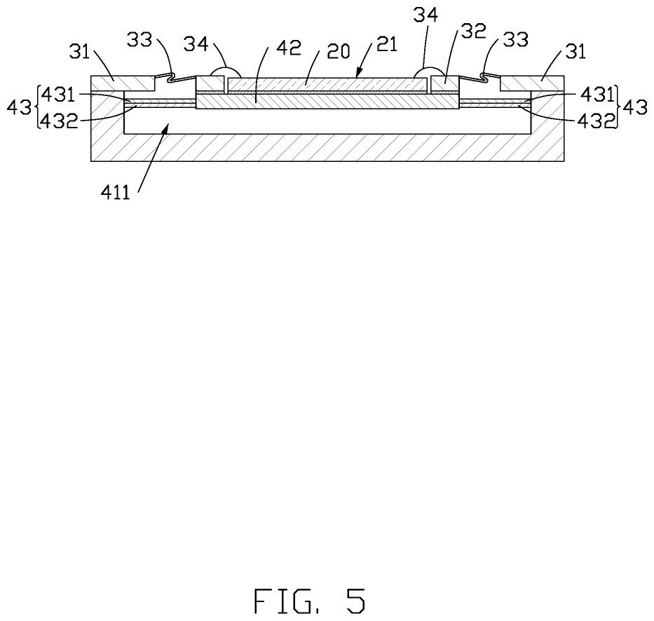

In one embodiment, the second circuit board 32 defines a second opening 321, the photosensitive element 20 is arranged in the second opening 321 and is electrically connected to the second circuit board 32. Optionally, the photosensitive element 20 is connected to the second circuit board 32 through a wire 34 (as shown in FIG. 5). Optionally, the wire 34 may be gold wire. Optionally, the supporting plate 50 is connected to the first circuit board 31, and is spaced from the second circuit board 32, so a gap exists between the supporting plate 50 and the second circuit board 32, and at least part of the wire is arranged in the gap.

In one embodiment, the camera module 100 further includes an electrical connector 70. The electrical connector 70 is connected to the first circuit board 31, and the electrical connector 70 is used for electrically connecting to an external image processing device and/or an external power supply. Optionally, the first circuit board 31 and the electrical connector 70 are connected through the flexible circuit board 33 to facilitate adjustment of the position of the electrical connector 70 so that it is electrically connected to the external image processing device and/or the external power supply.

Referring to FIG. 2, FIG. 3, and FIG. 4, in one embodiment, the focusing assembly 40 includes a first metal plate 41, a second metal plate 42, and a plurality of connecting members 43. One end of each connecting member 43 is connected to the first metal plate 41, and other end of each connecting member 43 is connected to the second metal plate 42, and the first metal plate 41 and the second metal plate 42 are arranged at intervals. The first circuit board 31 is connected to the first metal plate 41, and the second circuit plate 32 is connected to the second metal plate 42. The photosensitive element 20 is not thermally insulated from one side of the second metal plate 42 away from the first metal plate 41. The heat of the photosensitive element 20 is transmitted to the connecting members 43 through the second metal plate 42. When the temperature of the connecting member 43 changes, the connecting member 43 deforms, so as to make the second metal plate 42 move relative to the first metal plate 41, thus moving the photosensitive element 20 far away from or closer to the camera lens 12.

Optionally, the photosensitive element 20 is in contact with and connects the second metal plate 42. Optionally, the photosensitive element 20 is connected to the second metal plate 42 through thermally conductive adhesive.

In one embodiment, the first metal plate 41 defines a first concavity 411, and the second metal plate 42 is arranged in the first concavity 411. The second metal plate 42 includes a first side 421, a second side 422, a third side 423, and a fourth side 424, the first side 421 is arranged relative to the second side 422, and the third side 423 is arranged relative to the fourth side 424. The first side 421 is adjacent to one end of the third side 423 and the fourth side 424, and the second side 422 is adjacent to other ends of the third side 423 and the fourth side 424. The first side 421, the second side 422, the third side 423, and the fourth side 424 are all spaced from the edge of the first concavity 411, and the second metal plate 42 is spaced from the bottom surface of the first concavity 411 to the side surface facing the first metal plate 41. The vertical distance between the side surface of the second metal plate 42 facing the first metal plate 41 and the bottom surface of the first concavity 411 is the distance that the photosensitive element 20 can move along the optical axis direction of the camera lens 12.

In one embodiment, one end of part of the connecting members 43 is connected to the first side 421, and other end of part of the connecting members 43 is connected to the edge opposite the first concavity 411 and the first side 421, one end of part of the connecting members 43 is connected to the second side 422, and other end of part of the connecting members 43 is connected to the edge opposite the first concavity 411 and the second side 422. In another embodiment, one end of part of the connecting members 43 is connected to the third side 423, and other end of part of the connecting members 43 is connected to the edge opposite the first concavity 411 and the third side 423. One end of part of the connecting members 43 is connected to the fourth side 424, and other end of part of the connecting members 43 is connected to the edge opposite the first concavity 411 and the fourth side 424. Thus movement of the second metal plate 42 relative to the first metal plate 41 is realized by setting the connecting members 43 on the opposite sides of the second metal plate 42, it is unnecessary to dispose the connecting members 43 on each side of the second metal plate 42. Therefore, the volume of occupation is reduced, space utilization rate can be improved, and it is conducive to miniaturization.

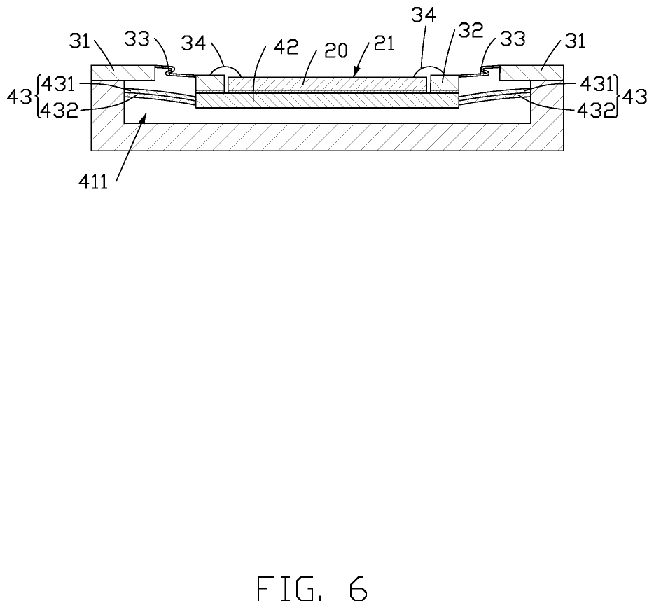

Referring to FIG. 5 and FIG. 6, in one embodiment, the connecting member 43 includes a first connecting plate 431 and a second connecting plate 432. The first connecting plate 431 is stacked with the second connecting plate 432. The second connecting plate 432 faces the first metal plate 41, and the first connecting plate 431 is connected to the side of the second connecting plate 432 which is away from the first metal plate 41. When the temperature of the first connecting plate 431 and the second connecting plate 432 changes, the first connecting plate 431 and the second connecting plate 432 are deformed, and the first connecting plate 431 and the second connecting plate 432 have different thermal expansion ratios. Optionally, the thermal expansion ratio of the first connecting plate 431 is greater than that of the second connecting plate 432. At the same temperature, the degree of deformation of the first connecting plate 431 is greater than that of the second connecting plate 432, and the degree of bending of the first connecting plate 431 is greater than the degree of bending of the second connecting plate 432, so that the second metal plate 42 moves towards the first metal plate 41. Optionally, the material of the first connecting plate 431 and of the second connecting plate 432 can be metal or metallic.

Referring to FIG. 5 and FIG. 6, when using the camera module 100, and the photosensitive element 20 is at a high temperature state after a long use, part of the heat of the photosensitive element 20 is transmitted to the lens assembly 10, causing the lens assembly 10 to be deformed by heat, so that the focal length between the lens assembly 10 and the photosensitive element 20 becomes longer. Part of the heat of the photosensitive element 20 is transmitted to the first connecting plate 431 and the second connecting plate 432 through the second metal plate 42. The temperature of the first connecting plate 431 and the second connecting plate 432 increases, and the first connecting plate 431 and the second connecting plate 432 are deformed, the deformation amount of the first connecting plate 431 is greater than that of the second connecting plate 432, so as to make the second metal plate 42 move away from the camera lens 12 and increase the focal length between the photosensitive element 20 and the lens assembly 10, so that the focus of the lens assembly 10 is on the photosensitive element 20, and ensures the imaging quality.

When the photosensitive element 20 is not being used and in the normal temperature state, the temperature of the lens assembly 10 decreases, and the focal length between the lens assembly 10 and the photosensitive element 20 recovers, the temperature of the first connecting plate 431 and the second connecting plate 432 decreases, and the deformation of the first connecting plate 431 and the second connecting plate 432 gradually fades, so that the second metal plate 42 moves closer to the camera lens 12, and the focus of the lens assembly 10 returns to the photosensitive element 20. The deformation temperature of the connecting member 43 can be determined by obtaining in advance the temperature drift simulation data of the camera lens 12, the calorific value simulation data of the photosensitive element 20, and the temperature difference data between the camera lens 12 and the photosensitive element 20.

After the heating of the photosensitive element 20 causes the focal length between the camera lens 12 and the photosensitive element 20 to become longer, the camera module 100 of the present disclosure generates deformation through the focusing assembly 40 to make the photosensitive element 20 move away from the camera lens 12, so as to adjust the focal length between the photosensitive element 20 and the camera lens 12, so that the focus of the camera lens 12 is located on the photosensitive element 20, so as to achieve automatic focusing and ensure the imaging quality.

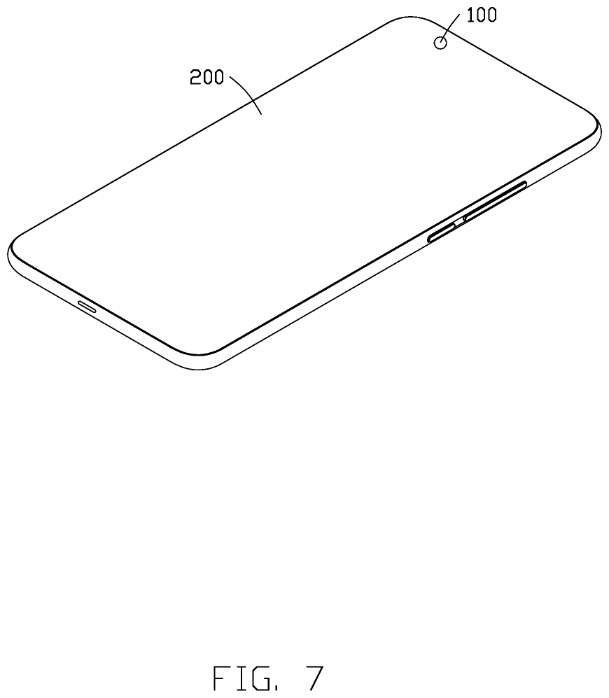

FIG. 7 illustrates an electronic photosensitive element 200 in accordance with an embodiment of the present disclosure.

The electronic device photosensitive element 200 includes a housing and a camera module 100, and the camera module 100 is installed on the housing for acquiring images. The electronic device photosensitive element 200 includes but is not limited to the electronic devices providing an imaging function, such as smart phones, car lenses, surveillance lenses, tablets, laptops, e-book readers, portable multimedia players (PMP), portable phones, video phones, digital still life cameras, mobile medical devices, wearable devices, etc.

Those of ordinary skill in the art should realize that the above embodiments are only used to illustrate the present disclosure, but not to limit the present disclosure. As long as they are within the essential spirit of the present disclosure, the above embodiments are appropriately made and changes fall within the scope of protection of the present disclosure.

What is claimed is:

1. A camera module comprising:
a lens assembly;
a photosensitive element configured for receiving light entering the lens assembly;
a circuit board electrically connected to the photosensitive element; and
a focusing assembly connecting to the photosensitive element; wherein the focusing assembly is arranged to produce deformation when temperature changes, to make the photosensitive element move away from or toward the lens assembly, thereby regulating a focal length between the photosensitive element and the lens assembly.

2. The camera module of claim 1, wherein the focusing assembly comprises a first metal plate, a second metal plate and a plurality of connecting members, one end of each of the plurality of connecting members is connected to the first metal plate, and another end of each of the plurality of connecting members is connected to the second metal plate, the first metal plate and the second metal plate are arranged at intervals, the photosensitive element is arranged on a surface of the second metal plate opposite to the first metal plate, the plurality of connecting members deforms as temperature changes, the second metal plate moves relative to the first metal plate as the plurality of connecting members deforms.

3. The camera module of claim 2, wherein the first metal plate defines a first concavity, and the second metal plate is arranged in the first concavity, the plurality of connecting members is connected to an edge of the first concavity and an edge of the second metal plate, and the second metal plate is spaced from the edge and a bottom of the first concavity.

4. The camera module of claim 2, wherein each of the plurality of connecting members comprises a first connecting plate and a second connecting plate arranged in a stack, the second connecting plate faces the first metal plate, the first connecting plate is away from the first metal plate, and a thermal expansion ration of the first connecting plate is different form a thermal expansion ration of the second connecting plate.

5. The camera module of claim 4, wherein the thermal expansion ratio of the first connecting plate is greater than the thermal expansion ratio of the second connecting plate, and a deformation amount of the first connecting plate is greater than a deformation degree of the second connecting plate at a same temperature.

6. The camera module of claim 2, wherein the circuit board comprises a first circuit board and a second circuit board, the first circuit board is connected to the first metal plate, the second circuit board is connected to the second metal plate, the first circuit board surrounds a periphery of the second circuit board, and the first circuit board is flexibly connected to the second circuit board, the second circuit board surrounds a periphery of the photosensitive element, and the second circuit board is electrically connected to the photosensitive element.

7. The camera module of claim 6, further comprising a supporting plate, wherein the supporting plate is connected to the first circuit board and is spaced apart from the second circuit board.

8. The camera module of claim 7, wherein the supporting plate defines an installation portion, and an optical filter is arranged in the installation portion, and the optical filter is located between the lens assembly and the photosensitive element.

9. The camera module of claim 8, wherein the lens assembly comprises a bracket and a camera lens, the camera lens is mounted on the bracket, and the bracket is connected to a side of the supporting plate away from the first circuit board.

10. The camera module of claim 6, further comprising an electrical connector, wherein the electrical connector is flexibly connected to the first circuit board, and the electrical connector is configured for connecting the camera module to an external device.

11. An electronic device comprising:
a camera module comprising:
a lens assembly;
a photosensitive element configured for receiving light entering the lens assembly;
a circuit board electrically connected to the photosensitive element; and
a focusing assembly connecting to the photosensitive element; wherein the focusing assembly is arranged to produce deformation when temperature changes, to make the photosensitive element move away from or toward the lens assembly, thereby regulating a focal length between the photosensitive element and the lens assembly.

12. The electronic device of claim 11, wherein the focusing assembly comprises a first metal plate, a second metal plate and a plurality of connecting members, one end of each of the plurality of connecting members is connected to the first metal plate, and another end of each of the plurality of connecting members is connected to the second metal plate, the first metal plate and the second metal plate are arranged at intervals, the photosensitive element is arranged on a surface of the second metal plate opposite to the first metal plate, the plurality of connecting members deforms as temperature changes, the second metal plate moves relative to the first metal plate as the plurality of connecting members deforms.

13. The electronic device of claim 12, wherein the first metal plate defines a first concavity, and the second metal plate is arranged in the first concavity, the plurality of connecting members is connected to an edge of the first concavity and an edge of the second metal plate, and the second metal plate is spaced from the edge and a bottom of the first concavity.

14. The electronic device of claim 12, wherein each of the plurality of connecting members comprises a first connecting plate and a second connecting plate arranged in a stack, the second connecting plate faces the first metal plate, the first connecting plate is away from the first metal plate, and a thermal expansion ration of the first connecting plate is different form a thermal expansion ration of the second connecting plate.

15. The electronic device of claim 14, wherein the thermal expansion ratio of the first connecting plate is greater than the thermal expansion ratio of the second connecting plate, and a deformation amount of the first connecting plate is greater than a deformation degree of the second connecting plate at a same temperature.

16. The electronic device of claim 12, wherein the circuit board comprises a first circuit board and a second circuit board, the first circuit board is connected to the first metal plate, the second circuit board is connected to the second metal plate, the first circuit board surrounds a periphery of the second circuit board, and the first circuit board is flexibly connected to the second circuit board, the second circuit board surrounds a periphery of the photosensitive element, and the second circuit board is electrically connected to the photosensitive element.

17. The electronic device of claim 16, further comprising a supporting plate, wherein the supporting plate is connected to the first circuit board and is spaced apart from the second circuit board.

18. The electronic device of claim 17, wherein the supporting plate defines an installation portion, and an optical filter is arranged in the installation portion, and the optical filter is located between the lens assembly and the photosensitive element.

19. The electronic device of claim 18, wherein the lens assembly comprises a bracket and a camera lens, the camera lens is mounted on the bracket, and the bracket is connected to a side of the supporting plate away from the first circuit board.

20. The electronic device of claim 16, further comprising an electrical connector, wherein the electrical connector is flexibly connected to the first circuit board, and the electrical connector is configured for connecting the camera module to an external device.
